(19) United States
(12) Patent Application Publication
(10) Pub. No.: US 2023/0376727 A1
(43) Pub. Date: Nov. 23, 2023

(54) INFORMATION PROCESSING DEVICE, INFORMATION PROCESSING METHOD, AND RECORDING MEDIUM

(71) Applicant: NEC Corporation, Minato-ku Tokyo (JP)

(72) Inventors: Shumpei KUBOSAWA, Tokyo (JP); Takashi Onishi, Koto-ku, Tokyo (AD)

(73) Assignee: NEC Corporation, Minato-ku Tokyo (JP)

(21) Appl. No.: 18/031,106

(22) PCT Filed: Oct. 29, 2020
(86) PCT No.: PCT/JP2020/040612

§ 371 Date: Apr. 10, 2023

(51) Int. Cl. G06N 3/0442; G06N 3/08

(52) U.S. Cl. CPC G06N 3/0442; G06N 3/08

(57) ABSTRACT

An information processing device acquires training data. The training data includes time-series data of a measurement item regarding a target and time-series data of an item that influences the target. The information processing device trains, by using the training data, a model that receives an input of time-series data of the measurement item and outputs time-series data of the item that influences the target.

### TECHNICAL FIELD

The present invention relates to an information processing device, an information processing method, and a recording medium.

### BACKGROUND ART

Simulators are used in some cases to understand plant characteristics or plant behaviors in abnormal conditions (for example, see Patent Document 1).

### PRIOR ART DOCUMENTS

### Patent Documents

Patent Document 1: Japanese Unexamined Patent Application, First Publication No. H07-334070

### SUMMARY OF THE INVENTION

### Problems to be Solved by the Invention

With use of a simulator, it is possible to estimate the behavior of a target such as a plant. On the other hand, it is difficult, in general, to calculate input-equivalent data corresponding to output-equivalent data, using a simulation model inversely. For this reason, it is difficult to estimate the factor of an event detected in relation to a target by means of simulation. In contrast to this, it is preferable to be able to estimate the factor of an event detected in relation to a target in cases of estimating the factor of an abnormality when the abnormality is detected in a target, for example.

An example object of the present invention is to provide an information processing device, an information processing method, and a recording medium capable of solving the problems mentioned above.

### Means for Solving the Problem

According to a first example aspect of the present invention, an information processing device includes: a training data acquisition means that acquires training data, the training data including time-series data of a measurement item regarding a target and time-series data of an item that influences the target; and a learning means that trains, by using the training data, a model that receives an input of time-series data of the measurement item and outputs time-series data of the item that influences the target.

According to a second example aspect of the present invention, an information processing method executed by a computer includes: acquiring training data, the training data including time-series data of a measurement item regarding a target and time-series data of an item that influences the target; and training, by using the training data, a model that receives an input of time-series data of the measurement item and outputs time-series data of the item that influences the target.

According to a third example aspect of the present invention, a recording medium having recorded therein a program causing a computer to execute: acquiring training data, the training data including time-series data of a measurement item regarding a target and time-series data of an item that influences the target; and training, by using the training data, a model that receives an input of time-series data of the measurement item and outputs time-series data of the item that influences the target.

### Effect of the Invention

According to the information processing device, the information processing method, and the recording medium mentioned above, it is possible to estimate a factor of an event detected in relation to a target.

### BRIEF DESCRIPTION OF THE DRAWINGS

FIG. 1 A schematic block diagram showing an example of a functional configuration of an estimation device according to an example embodiment.

FIG. 2 A diagram showing an example of input/output data of a factor estimation model according to an example embodiment.

FIG. 3 A diagram showing an example of a structure of the factor estimation model for receiving designation of a non-estimation target item among items influencing a target in an example embodiment.

FIG. 4 A flowchart showing an example of a processing procedure for the estimation device according to an example embodiment to train a factor estimation model.

FIG. 5 A flowchart showing an example of a processing procedure for the estimation device according to an example embodiment to estimate an abnormality factor of a target 900 based on time-series data of measurement data.

FIG. 6 A flowchart showing an example of a processing procedure for the estimation device according to an example embodiment to update the factor estimation model.

FIG. 7 A diagram showing a configuration example of an information processing device according to an example embodiment.

FIG. 8 A diagram showing an example of a processing procedure in an information processing method according to an example embodiment.

FIG. 9 A schematic block diagram showing a configuration of a computer according to at least one example embodiment.

### EXAMPLE EMBODIMENT

Hereinafter, example embodiments of the present invention will be described, however, the invention within the scope of the claims is not limited by the following example embodiments. Furthermore, all the combinations of features described in the example embodiments may not be essential for the solving means of the invention.

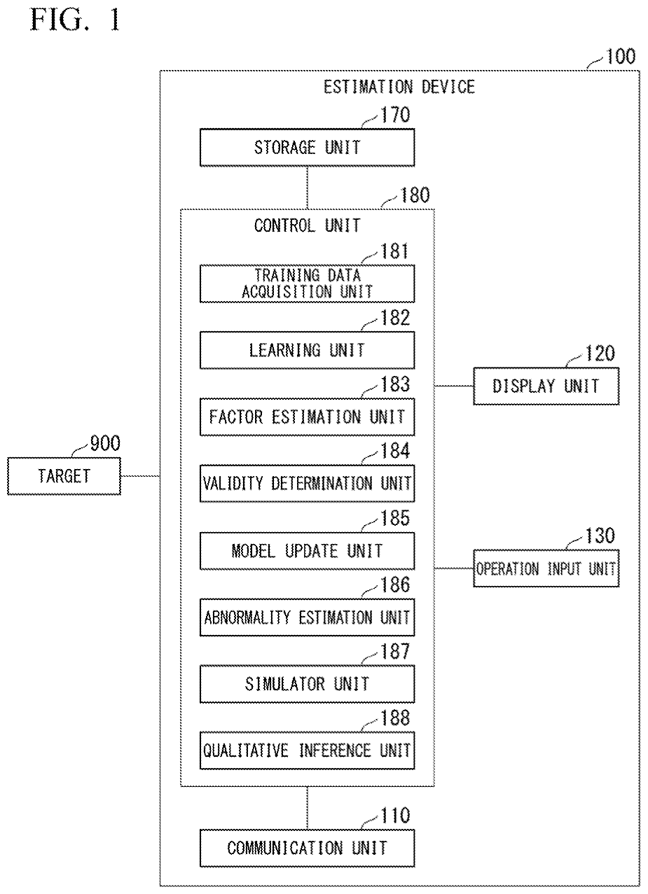

FIG. 1 is a schematic block diagram showing an example of a functional configuration of an estimation device according to an example embodiment. In the configuration shown in FIG. 1, an estimation device 100 includes a communication unit 110, a display unit 120, an operation input unit 130, a storage unit 170, and a control unit 180. The control unit 180 includes a training data acquisition unit 181, a learning unit 182, a factor estimation unit 183, a validity determination unit 184, a model update unit 185, an abnormality estimation unit 186, a simulator unit 187, and a qualitative inference unit 188.

Moreover, the estimation device 100 acquires measurement data related to a target 900, such as sensor measurement data transmitted by sensors provided in the target 900.

The estimation device 100 estimates time-series data of items that influence the target 900, based on time-series data of measurement data related to the target 900.

The estimation device 100 also includes the learning unit 182 to learn a model for estimating the factor of an abnormality in target 900. The estimation device 100 corresponds to an example of an information processing device.

The factor referred to here is something that has an influence on a result. The factor may include a cause. The cause referred to here is something that has a direct influence on a result.

The measurement data related to the target 900 may include data indicating output of the target 900 or data indicating a state of the target 900.

The output of the target 900 may be an operation of the target 900. Or, in those cases where the target 900 outputs matter or energy, the output of the target 900 may be the matter or energy that the target 900 outputs.

The state of the target 900 may be a state in which the quantity of a state, such as the temperature of a predetermined portion of the target 900, can be measured. Moreover, the state of the target 900 may include a state indicated by a discrete value, such as the open/closed state of a shutoff valve detected by a sensor provided in the shutoff valve.

Items that may possibly influence the target 900 may include operations performed on the target 900, such as a valve opening command for the target 900. The operations performed on the target 900 may include human-performed operations. Moreover, the operations performed on the target 900 may include machine-performed operations such as a control command from a control device that communicates with the target 900, for example.

Moreover, items with a possibility of influencing the target 900 may also include the state of the surrounding environment of the target 900. The state of the surrounding environment of the target 900 may be a state that can be measured by installing a sensor on or around the target 900, such as the temperature or the humidity in the room where the target 900 is installed.

The state of the surrounding environment of the target 900 may also include the state of input to the target 900, such as the flow rate of a raw material or a fuel input to the target 900.

The target 900 may be various things which can act from the outside of the target 900, and for which data related to at least either the output or the state of the target 900 can be measured. For example, the target 900 may be a robot, a machine tool, or a device such as a moving body. Alternatively, the target 900 may be a facility provided with multiple devices, such as a factory or a power plant.

For example, the target 900 may be an industrial robot. In such a case, the estimation device 100 may receive an input of time-series data of the operation of the target 900 from the sensor provided in the target 900 and estimate time-series data of a control command value inputted to the target 900.

Alternatively, the target 900 may be a chemical plant. In such a case, time-series data of measured values of the state of the target 900 obtained by a sensor provided on the target 900, and measured values of the product state obtained by a sensor provided for quality control of the product produced by the target 900 may be used as input data to the estimation device 100. Then, the estimation device 100 may estimate time-series data of the control command value for the target 900, the state of the raw material input to the target 900, and the sensor measurement value of the surrounding environment of the target 900, such as the temperature around the target 900.

Data measured by an actual device of the target 900 is also referred to as measurement data related to the target 900 or simply as measurement data.

Not only data measured by the actual machine of the target 900, but also data of a measurement target item for the target 900 is also referred to as measurement item data related to the target 900, or simply as measurement item data.

The measurement data and the measurement item data are data of the same item, and are represented by a vector in which the value for each item serves as an element thereof. The measurement data and the measurement item data may both be represented by a real vector. Alternatively, in cases such as where the measurement items include the ON/OFF of a shutoff valve, the measurement data or the vector representing the measurement item data may have real-valued elements and discrete-value elements.

Time-series data of measurement data are data in which a plurality of pieces of measurement data with different measurement times are put together. The time-series data of measurement data are also referred to as time-series data of measurement data related to the target 900.

Time-series data of measurement item data are data that include a plurality of pieces of measurement item data with different measurement times. However, as mentioned above, the measurement item data are not limited to being actual measurement data. Therefore, the measurement time mentioned here may be virtual. The time-series data of measurement item data are also referred to as time-series data of measurement item data related to the target 900.

Items that may influence the target 900 are also referred to as influencing items. Data of items that may influence the target 900 are also referred to as influencing item data of the target 900 or simply as influencing item data.

The influencing item data are indicated by a vector in which the value for each item serves as an element thereof. The influencing item data may be represented by a real vector. Alternatively, in cases such as where operations performed on the target 900 include the ON/OFF operation of a switch, the influence item data may have real-valued elements and discrete-valued elements.

The time-series data of the influencing item data are data in which a plurality of influencing item data with different times are put together. The time-series data of influencing item data are also referred to as time-series data of influencing items or time-series data of influencing items of the target 900.

Either or both of the measurement item data and the influencing item data may include values of items obtained by calculation such as heat transfer coefficient rather than by actual measurement.

The estimation device 100 acquires, through learning, a model that outputs time-series data of influencing items in response to input of time-series data of measurement items. The estimation device 100 performs training of the model, using training data including the time-series data of measurement items and the time-series data of influencing items.

Also, when an abnormality occurs in the target 900, the estimation device 100 estimates the factor of the abnormality. For example, based on the time-series data of measurement data at and before the time when an abnormality is detected, the estimation device 100 estimates the time-series data of the influencing items at and before the time when the abnormality is detected. Moreover, based on the time-series data of measurement items at normal times, the estimation device 100 estimates the time-series data of the influencing items at normal times. The estimation device 100 then estimates an item, for which a value that differs by a predetermined condition or more between normal and abnormal states, as the factor of an abnormality.

The communication unit 110 communicates with other devices according to the control of the control unit 180. For example, the communication unit 110 receives measurement data related to the target 900, such as sensor measurement data transmitted by a sensor provided on the target 900. Also, in the case where training data for the learning unit 182 to perform learning of abnormality factor estimation of the target 900 is in another device, the communication unit 110 may communicate with the device to acquire the training data.

The display unit 120 includes a display screen such as a liquid crystal panel or an LED (light emitting diode) panel, and displays various types of images. For example, the display unit 120 displays the result of estimating the factor of an abnormality in the target 900 obtained by the abnormality estimation unit 186.

The operation input unit 130 includes input devices such as a keyboard and a mouse, and accepts user operations. For example, the operation input unit 130 accepts a user operation for designating an item to be excluded from the abnormality factor candidates among the operation items for the target 900.

The storage unit 170 stores various types of data. The storage unit 170 is configured using a storage device included in the estimation device 100.

In particular, the storage unit 170 stores a model that simulates the operation of the target 900. The model that simulates the operation of the target 900 is also referred to as a simulation model.

Moreover, the storage unit 170 also stores a model for estimating the factor of an abnormality in the target 900. The model for estimating the factor of an abnormality in the target 900 is also referred to as a factor estimation model.

The factor estimation model and the simulation model have a relationship in which input data and output data are inversed.

Specifically, the input data to the simulation model are time-series data of influencing items. The output data of the simulation model are time-series data of measurement items obtained by simulating the operation of the target 900 in accordance with the operation indicated by input data and the state of the surrounding environment.

On the other hand, the input data to the factor estimation model are time-series data of measurement items. The output data of the factor estimation model are time-series data of influencing items indicating the operation performed on the target 900 and the state of the surrounding environment, that are estimated to cause the state and the output of the target 900 indicated by the time-series data of the measurement item.

In this regard, it can be said that the factor estimation model is an inverse model of the simulation model.

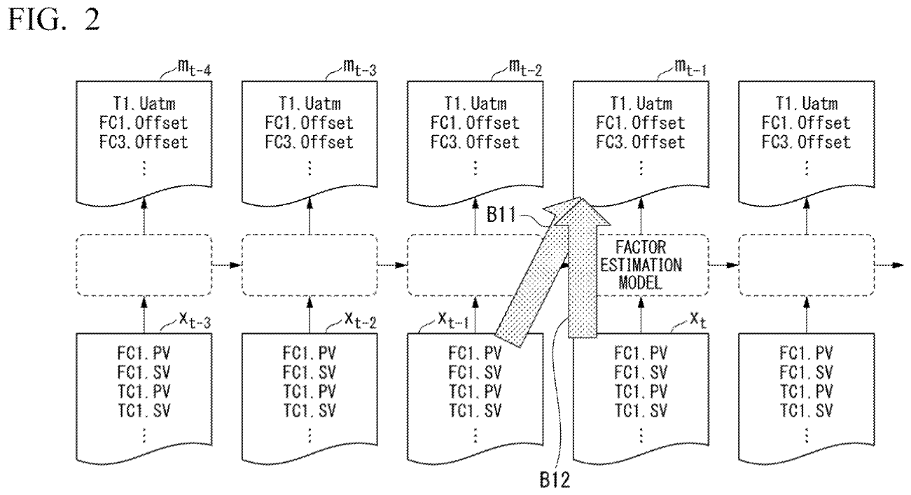

FIG. 2 is a diagram showing an example of input/output data of the factor estimation model.

In FIG. 2, “t−4”, “t−3”, “t” indicate times in time steps. Data mₜ₋₄, mₜ₋₃, mₜ₋₂, and mₜ₋₁ correspond to examples of the influencing item data at respective times. The series of data mₜ₋₄, mₜ₋₃, mₜ₋₂, and mₜ₋₁ are examples of the time-series data of influencing items.

Data xₜ₋₃, xₜ₋₂, xₜ₋₁, and xₜ correspond to examples of measurement item data at respective times. The series of data xₜ₋₃, xₜ₋₂, xₜ₋₁ and xₜ correspond to examples of the time-series data of measurement items.

The factor estimation model receives inputs of measurement item data and outputs influence item data. In the example of FIG. 2, the factor estimation model receives an input of data xₜ₋₃ and outputs data mₜ₋₄. The factor estimation model further receives an input of data xₜ₋₂ and outputs data mₜ₋₃. The factor estimation model further receives an input of data xₜ₋₁ and outputs data mₜ₋₂. The factor estimation model further receives an input of data xₜ and outputs data mₜ₋₁.

It can be said that for the state and the output of the target 900 at a certain time, the operation performed for the target 900 and the state of the surrounding environment at an earlier time have a factor relationship with the result. For example, it can be said that the operation performed for the target 900 and the state of the surrounding environment of the target 900 indicated by the data mₜ₋₄, mₜ₋₃, mₜ₋₂, and mₜ₋₁ are the factors that cause the state and output of the target 900 to be the state and output indicated by the data xₜ.

In this regard, according to the factor estimation model, it is possible to estimate the factor of the state and the output of the target 900.

In particular, the factor estimation model outputs time-series data of influencing items. As a result, even if the length of time is unknown from the time of an operation performed on the target 900 or the state of the surrounding environment to the time at which the effect emerges on the state and the output of the target 900, the estimation device 100 can estimate the factor of the abnormality in the target 900, using the factor estimation model.

For example, here is considered a case where an abnormal state of the target 900 is indicated by data xₜ, and the operation or the surrounding environment state causing the abnormality are indicated by any one or more of data mₜ₋₄, mₜ₋₃, mₜ₋₂, or mₜ₋₁. In such a case, from the operations performed on the target 900 and the surrounding environment states indicated by data mₜ₋₄, mₜ₋₃, mₜ₋₂, and mₜ₋₄, the estimation device 100 can detect the operation or the surrounding environment state estimated as the factor of the abnormality and suggest it to the user as a result of abnormality factor estimation.

The method by which the estimation device 100 detects an abnormality from the state or the output of the target 900 is not limited to a particular method. For example, the display unit 120 may display time-series data of measurement items, and the operation input unit 130 may accept a user operation to select an abnormal state or an abnormal output from among the states or the outputs of the target 900 indicated by the time-series data of measurement items. In such a case, not only for an abnormality, the user may select the state or the output, the factor of which the user desires to know.

Alternatively, the storage unit 170 may preliminarily store an abnormality determination threshold value for each of the state and the output of the target 900. Then, the estimation device 100 may detect an abnormality by comparing the value indicated by measurement item data with the abnormality determination threshold value for each measurement item related to the target 900.

As a method for the estimation device 100 to detect the operation or the surrounding environment state estimated to be the factor of an abnormality from among the operations on the target 900 and the surrounding environment state, for example, a statistical method may be used in addition to or instead of the method described above in which comparison with the normal value is performed.

For example, the storage unit 170 may preliminarily store data indicating a correlation between the state or the output of the target 900, and the operation on the target 900 or the surrounding environment state, obtained by statistically analyzing data having multiple combinations of time-series data of measurement items and time-series data of influencing items.

Then, when an abnormality is detected from the state or the output of the target 900, the estimation device 100 may detect, as the result of abnormality factor estimation, an operation or a surrounding environment state having a positive correlation equal to or higher than a predetermined threshold value with the detected abnormality, among operations on the target 900 and surrounding environment states at times before the time at which the abnormality occurred. The estimation device 100 may select a plurality of operations or surrounding environment states as the result of abnormality factor estimation.

However, the method by which the estimation device 100 detects, from among operations on the target 900 and surrounding environment states, an operation or a surrounding environment state estimated to be the factor of the abnormality is not limited to a particular method.

Arrows B11 and B12 in FIG. 2 indicate an example of a case where the factor estimation model calculates data mₜ₋₁ based on data xₜ₋₁ and xₜ. In this way, the factor estimation model is expected to be able to perform highly accurate estimation by estimating the operation on the target 900 and the surrounding environment state at a certain time based on the states and the outputs of the target 900 at multiple times.

In the case where the estimation device 100 acquires measurement data related to the target 900 in a real-time manner, a model having an internal state is used as the factor estimation model.

For example, the estimation device 100 may perform learning using a naive recurrent neural network (RNN), to configure the factor estimation model. Alternatively, the estimation device 100 may perform learning using a long short-term memory (LSTM), which is a type of recurrent neural network, to configure the factor estimation model.

However, the method of configuring the factor estimation model is not limited to a particular method. As a method of configuring the factor estimation model, various model configuration methods that performs learning using a model having an internal state can be used.

As described above, by using a model having an internal state as the factor estimation model, even in the case where the estimation device 100 acquires measurement data in a real-time manner, it is possible to estimate the operation on the target 900 and the surrounding environment state at a given time, based on the state and the output of the target 900 at a plurality of times.

Also, the factor estimation model receives an output of time-series data of measurement items and outputs time-series data of influencing items, so that the estimation device 100 can perform factor estimation in those cases where the length of time is unknown from the time at which the operation or the surrounding environment state corresponding to the factor occurred, to the time at which the operation or the output of the target 900 corresponding to the result occurred.

The storage unit 170 also stores a logical model that indicates qualitative behavior of the target 900. The logical model, which indicates qualitative behavior of the target 900, is also referred to as a qualitative inference model.

The estimation device 100 determines the validity of output data of the factor estimation model, using the qualitative inference model.

The control unit 180 controls each unit of the estimation device 100 and executes various processes. Functions of the control unit 180 are executed by a CPU (central processing unit) included in the estimation device 100 reading out a program from the storage unit 170 and executing the program.

The training data acquisition unit 181 acquires training data for learning the factor estimation model. In particular, the training data acquisition unit 181 acquires training data that include time-series data of measurement items and time-series data of influencing items.

The training data acquisition unit 181 corresponds to an example of the training data acquisition means.

Here, it is difficult, in general, to calculate input-equivalent data corresponding to output-equivalent data, using a simulation model inversely. As for the target 900 also, it is conceivable that time-series data of influencing items cannot be acquired from time-series data of measurement items, using a simulation model.

Therefore, the training data acquisition unit 181 acquires training data, and the learning unit 182 uses the training data to perform learning of the factor estimation model. The estimation device 100 can estimate time-series data of influencing items from time-series data of measurement items by using the factor estimation model.

Also, the estimation device 100 can configure the factor estimation model through learning using a recurrent neural network or a long short-term memory as mentioned above.

The training data acquisition unit 181 may acquire training data that is based on the results of the simulator unit 187 simulating the target 900.

Here, it is generally considered that the frequency of anomalies occurring in a facility or the like is not high. If the frequency of abnormality occurrence in the target 900 is not high, it is conceivable that actual measurement data at abnormal times cannot be obtained sufficiently. Also, in the case where the frequency of abnormality occurrence differs depending on the type of abnormality in the target 900, it is conceivable that actual measurement data on anomalies with a low occurrence frequency cannot be obtained sufficiently.

Although it is conceivable that an operation performed on the target 900 can artificially cause an abnormality to occur, it is considered difficult to artificially cause an abnormality from the safety or economy standpoint. Moreover, it is considered difficult to exhaustively identify anomalies that can occur in the target 900 and operations that cause the anomalies. Furthermore, there may be cases where it is difficult to execute an operation to cause an abnormality, such as where a delicate operation is required to cause an abnormality.

On the other hand, with the simulator unit 187 simulating the behavior of the target 900 with various input data input to the simulation model, it is possible to obtain data of the state and the output of the target 900 regarding various operations and surrounding environment states in various situations. Even when an abnormality occurs in the target 900, it is expected to be possible to obtain training data.

In this way, even in the case where it is difficult to acquire data of an abnormal time using the actual target 900, the training data acquisition unit 181 can acquire data of the abnormal time by simulating the operation of the target 900.

The training data acquisition unit 181 may acquire data obtained by adding noise to simulation result data of the target 900 as training data. For example, the training data acquisition unit 181 may synthesize noise into the simulation result data of the target 900.

As a result, when measurement data acquired by the estimation device 100 contains noise, training data can be obtained with highly accurate measurement data approximation, and it is expected that highly accurate training of the factor estimation model can be performed.

In addition to or instead of data based on the simulation result of the target 900, the training data acquisition unit 181 may acquire training data that include actual measurement data obtained in the target 900.

It is conceivable that, depending on the type of the target 900, training data can be obtained even in those cases where the frequency of abnormality occurrence is relatively high and anomalies are occurring. In such a case, it is expected that highly accurate learning can be performed by training the factor estimation model using actual measurement data.

The learning unit 182 uses training data acquired by the training data acquisition unit 181 to perform training of the factor estimation model described above.

The learning unit 182 corresponds to an example of the learning means.

The factor estimation unit 183 inputs measurement item data into the factor estimation model and calculates influencing item data. The factor estimation unit 183 repeatedly inputs measurement item data to the factor estimation model in the order according to time steps. Thereby, the factor estimation unit 183 inputs the time-series data of measurement items to the factor estimation model.

The factor estimation unit 183 calculates influencing item data each time measurement item data is input to the factor estimation model. As a result, the factor estimation unit 183 calculates time-series data of influencing items.

It can be said that the time-series data of influencing items calculated by the factor estimation unit 183 indicate the operation on the target 900 and the surrounding environment state, that are the factors of the state and the output of the target 900 indicated by the time-series data of the estimation item data input to the factor estimation model. In this way, the factor estimation unit 183 estimates the operation on the target 900 and the surrounding environment state, which are the factors of the state and the output of the target 900.

In particular, the factor estimation unit 183 receives designation of a non-estimation target item among items influencing the target 900, and estimates the value of the item that is not a non-estimation target. For example, the factor estimation unit 183 adjusts the factor estimation model so that the value of the item designated as a non-estimation target item becomes a value predetermined as the value of the item at the time the target 900 is in the normal state. Then, the factor estimation unit 183 calculates the time-series data of the influencing items, using the factor estimation model that has been adjusted.

The factor estimation unit 183 corresponds to an example of the estimation means.

FIG. 3 is a diagram showing an example of the structure of the factor estimation model for receiving designation of a non-estimation target item among items influencing the target 900.

FIG. 3 shows an example of a case where the factor estimation model is configured using a neural network model. The neural network exemplified in FIG. 3 has an input layer L11, intermediate layers L12, L13, L14, an output layer L15, and a mask designation layer L16.

The input layer L11 receives an input of data xₜ, which are measurement item data at time t. The output layer L15 outputs data mₜ₋₁, which are influencing item data at time “t−1”. The mask designation layer L16 receives an input of data Pt indicating mask designation at time t.

The mask referred to here is a piece of information that designates a non-estimation target item among the items that influence the target 900. For example, the user determines a non-estimation target item, and designates it to the estimation device 100 through a user operation using the operation input unit 130.

For example, in the case where the degree of opening of an adjustment valve included in the target 900 is obviously remaining at a normal value and has not changed, the user may designate this adjustment valve as a non-estimation target item.

A plurality of items may concurrently be designated as non-estimation targets.

When a non-estimation target item has been designated, the target 900 adjusts the factor estimation model so that, for example, the value of the designated item becomes a value predetermined as the normal value of the target 900.

In such a case, it is necessary to adjust the factor estimation model so that the values of items other than the designated items are not inconsistent with the values of the measurement item data.

Accordingly, the factor estimation unit 183 temporarily adjusts the factor estimation model so that not only the operation amount at the location of the non-estimation target operation, but also the operation amount at other operation locations are consistent with the value of the measurement item data.

The method for the factor estimation unit 183 to adjust the factor estimation model is not limited to a particular method. For example, in the case where the factor estimation model is configured using a neural network, the factor estimation unit 183 may perform any of or a combination of the following. “Switch the input to one or more nodes to constant values”, “bias the input to one or more nodes”, “rewrite the weight coefficient of one or more edges”, or “switch part or all of the neural network to another neural network”.

The learning unit 182 or the factor estimation unit 183 may preliminarily learn the method of adjusting the factor estimation model for each item or each combination of items that may be designated.

For example, the training data acquisition unit 181 prepares a plurality of sets of time-series data indicating operations on the target 900, in which the operation amount at the location of operation designated as a non-estimation target is set to a value predetermined as the normal operation amount.

The simulator unit 187 inputs the time-series data prepared by the training data acquisition unit 181, into the simulation model and performs a simulation.

The training data acquisition unit 181 generates training data in which the prepared time-series data indicating the operation on the target 900 are linked to the time-series data indicating the state and the output of the target 900 based on the simulation result using the data.

The learning unit 182 uses the training data generated by the training data acquisition unit 181 to learn the method of adjusting the factor estimation model for satisfying the input/output of the factor estimation model indicated in the training data.

For example, in the case where there are n operation locations that can be designated as non-estimation targets, and any of the operation locations can be designated as non-estimation targets independently of other operation locations, there are 2ⁿ methods of selecting whether or not to designate these operation locations as non-estimation targets. Here, n is an integer where n≥1.

The learning unit 182 preliminarily learns the method of adjusting the factor estimation model, for each of these 2ⁿ selection methods. In the case where a non-estimation target operation location is designated while operating the estimation device 100, the factor estimation unit 183 adjusts the factor estimation model, using the adjustment method learned for the designated operation location. As a result, the factor estimation model outputs the time-series data of operation amount such that the operation amount at the operation location designated as a non-estimation target becomes the predetermined operation amount.

In this way, the factor estimation unit 183 receives designation of a non-estimation target item among the items that influence the target 900, and estimates the value of the item that is not a non-estimation target item, so that estimation target factors can be narrowed down. In this regard, the factor estimation unit 183 is expected to be able to perform highly accurate estimation of the factor of an event detected in relation to the target 900.

The validity determination unit 184 determines the validity of output data of the factor estimation model, based on input data to the factor estimation model.

The validity determination unit 184 corresponds to an example of the validity determination means.

The validity determination unit 184 may use qualitative inference performed by the qualitative inference unit 188 to determine the validity of output data of the factor estimation model. In particular, the validity determination unit 184 may determine the validity of output data of the factor estimation model, based on the consistency between the inference result obtained through qualitative inference using the qualitative expression of the output data of the factor estimation model, and the input data to the qualitative inference model.

For example, the validity determination unit 184 replaces the operation amount and the amount of the surrounding environment state indicated in the output data of the factor estimation model, with a qualitative expression such as small, medium, or large. The validity determination unit 184 compares, for example, the operation amount with a threshold value defined for each operation location, and replaces the operation amount with a qualitative expression based on the comparison result. Also, the validity determination unit 184 compares, for example, the amount of the surrounding environment state with a threshold value defined for each surrounding environment item, and replaces the state amount with a qualitative expression based on the comparison result.

Then, the validity determination unit 184 inputs the qualitative expression of the output data of the factor estimation model to the qualitative inference model, to thereby acquire an inference result. The inference result indicates the values related to the state amount of the target 900 and the output of the target 900 in a qualitative expression by indicating, for example, the temperature of a given portion of the target 900 being low, medium, or high.

Moreover, the validity determination unit 184 compares the state amount indicated in the measurement data, which is the input to the factor estimation model, with a predetermined threshold value, and replaces the state amount with a qualitative expression, based on the comparison result. Also, the validity determination unit 184 compares the amount related to the output of the target 900 indicated in the measurement data, which is the input to the factor estimation model, with a predetermined threshold value, and replaces the amount related to the output of the target 900 with a qualitative expression, based on the comparison result.

The validity determination unit 184 compares the inference result of the qualitative inference model and the qualitative expression of the output data of the factor estimation model, and determines whether or not they are consistent with each other. For example, in a case where the inference result of the qualitative inference model and the qualitative expression of the output data of the factor estimation model match with each other for a predetermined ratio or higher of items among all items, the validity determination unit 184 may determine that they are consistent with each other.

If the inference result of the qualitative inference model and the qualitative expression of the output of the factor estimation model are determined as being consistent with each other, the validity determination unit 184 determines the output data of the factor estimation model as being valid.

The validity determination unit 184 may determine the validity of the output data of the factor estimation model by comparing the simulation result obtained by inputting the output data of the factor estimation model to the simulator of the target 900, with the input data to the factor estimation model.

For example, when the communication unit 110 receives measurement data, the factor estimation unit 183 inputs the measurement data to the factor estimation model and acquires output data of the factor estimation model.

Also, the simulator unit 187 inputs the output data of the factor estimation model to the simulation model, to acquire a simulation result.

The validity determination unit 184 determines the validity of the output data of the factor estimation model, by comparing the output data of the factor estimation model, and the simulation result.

For example, the validity determination unit 184 calculates the ratio of the error between the value of each item indicated in the input to the factor estimation model, and the value of the same item indicated in the simulation result, to the magnitude of the value of that item. If the calculated ratio of the error is equal to or less than a predetermined threshold value for all items, the validity determination unit 184 determines the output data of the factor estimation model as being valid.

If the output data of the factor estimation model is determined as not being valid, the setting for factor estimation may be changed, for example, by means of the validity determination unit 184 setting the non-estimation target item as described above. Then, the abnormality estimation unit 186 may again perform estimation of the factor, using the factor estimation model after setting.

The model update unit 185 updates the factor estimation model, using measurement data. As described above, the measurement data referred to here are actual measurement data of the target 900.

The model update unit 185 corresponds to an example of the model update means.

For example, the model update unit 185 acquires time-series data of measurement data, and time-series data of influencing items at that time. As for the time-series data of the influencing items, the history of operations on the actual machine of the target 900 and the surrounding environment states may be recorded manually or automatically. Alternatively, in the case where a patterned operation is performed on the target 900 operating in the auto mode or the like, the model update unit 185 may acquire the time-series data of the patterned operation, and the time-series data of the measurement data obtained during the operation caused by the patterned operation.

The model update unit 185 first updates the simulation model, using the obtained time-series data of the influencing item and the time-series data of the measurement data. It is expected that the model can be updated highly accurately with less data than the case of updating the factor estimation model by means of machine learning in a case such as the simulation model being configured as a model that describes the behavior of the target 900.

Next, the model update unit 185 instructs the training data acquisition unit 181 to generate training data. The training data acquisition unit 181 uses the updated simulation model to generate training data for learning of the factor estimation model. For example, the training data acquisition unit 181 generates a plurality of sets of time-series data of the influencing item. The simulator unit 187 inputs the time-series data of the influencing items generated by the training data acquisition unit 181 into the simulation model, and acquires the time-series data of the measurement item for each time-series data of the influencing item. The training data acquisition unit 181 generates training data of the factor estimation model by associating the time-series data of the influencing item with the time-series data of the measurement item.

The model update unit 185 instructs the learning unit 182 to perform training of the factor estimation model. The learning unit 182 uses the training data generated by the training data acquisition unit 181, to perform training of the factor estimation model. Accordingly, the model update unit 185 updates the factor estimation model in accordance with the actual machine of the target 900. As a result, it is possible to reflect changes in characteristics, such as aging degradation of the actual machine of the target 900, in the factor estimation model, and in this regard, it is possible to improve the accuracy of the factor estimation model.

The abnormality estimation unit 186 estimates an abnormality related to the target 900.

The abnormality estimation unit 186 corresponds to an example of the abnormality estimation means.

Specifically, the abnormality estimation unit 186 determines whether or not an abnormality is present, using measurement data. For example, the abnormality estimation unit 186 compares the measurement data with the measurement item data obtained in the normal state of the target 900, determines whether or not there is an item indicating a value that deviates from the value in the normal state by a predetermined condition or more, and an abnormality is determined as being present if an applicable item is determined as present.

If an abnormality is determined as being present, the abnormality estimation unit 186 detects the time of the abnormality occurrence, the location of the abnormality in the target 900, and the content of the abnormality. The abnormality estimation unit 186 may detect the state amount measured at the location of the abnormality occurrence as the content of the abnormality.

Alternatively, the abnormality estimation unit 186 may estimate an abnormality related to the target 900, based on the time-series data of the influencing item in addition to or instead of the abnormality determination based on the measurement data described above. Specifically, the abnormality estimation unit 186 estimates an abnormality related to the target 900, based on the time-series data of the influencing item calculated by inputting the time-series data of the measurement data into the factor estimation model.

For example, the abnormality estimation unit 186 compares the time-series data of the influencing item with the time-series data of the influencing item in the normal state of the target 900, and determines whether or not there is an item that deviates from the normal value by a predetermined condition or more. If an applicable item is determined as being present, the abnormality estimation unit 186 determines an abnormality as being present in the target 900.

If an abnormality is determined as being present, the abnormality estimation unit 186 may further estimate the location of the abnormality in the target 900 and the content of the abnormality.

For example, based on the data mentioned above indicating a correlation between: the state or the output of the target 900; and the operation on the target 900 or the surrounding environment state, the abnormality estimation unit 186 estimates, as an abnormality occurrence item, the item, among the measurement items, having a correlation equal to or higher than a predetermined condition with the influencing item determined as having an abnormality. The abnormality estimation unit 186 may detect the value of the abnormality occurrence item as the content of the abnormality.

When an abnormality occurs due to an operation performed on the target 900, it is conceivable that the operation that causes the abnormality is different from the normal operation. Also, there is a time lag between the moment at which the operation that causes an abnormality is performed and the moment at which the abnormality occurs, and it is conceivable that detection of the operation that causes an abnormality can be performed more quickly than detection of the abnormality itself. The abnormality estimation unit 186 estimates an abnormality related to the target 900 based on the time-series data of operations calculated by the factor estimation unit 183, so that it is expected to be able to detect the possibility of an abnormality before the abnormality is detected.

Similarly, also in the case where an abnormality is caused by the state of the surrounding environment of the target 900, according to the abnormality estimation unit 186, it is expected to be able to detect the possibility of an abnormality before the abnormality is detected.

Also, when an abnormality occurs in the target 900, a case is conceivable where data that approximates the data in the normal state can be obtained as measurement data by performing an operation corresponding to the abnormality. In such a case, rather than using measurement data to detect an abnormality, detecting an abnormality using the data of operations on the target 900 will results in a greater difference from the normal state, and therefore there is a possibility of a successful abnormality detection with even higher accuracy. The abnormality estimation unit 186 estimates an abnormality related to the target 900 based on the time-series data of operations calculated by the factor estimation unit 183, so that it is expected to be able to detect an abnormality with even higher accuracy.

Similarly, also in the case where an abnormality is caused by the state of the surrounding environment of the target 900, according to the abnormality estimation unit 186, it is expected to be able to detect an abnormality with even higher accuracy.

Furthermore, if an abnormality is determined as being present, the abnormality estimation unit 186 estimates the factor of the abnormality. Specifically, as described above regarding the estimation device 100, the abnormality estimation unit 186 compares the time-series data of the operation on the target 900 in the normal state with the time-series data of the operation on the target 900 in the abnormal state. The abnormality estimation unit 186 then estimates an item, for which a value that differs by a predetermined condition or more between normal and abnormal states, as the factor of an abnormality.

The simulator unit 187 executes a simulation of the target 900 using the simulator. Specifically, the simulator unit 187 inputs the time-series data of the influencing item to the simulation model stored in the storage unit 170, and simulates the behavior of the target 900.

As described above regarding the training data acquisition unit 181, the simulator unit 187 executes a simulation of the target 900 so that the training data acquisition unit 181 acquires training data. Also, as described above regarding the validity determination unit 184, the simulator unit 187 executes a simulation of the target 900 in order for the factor estimation model 184 to determine the validity of the output data of the factor estimation model.

The qualitative inference unit 188 performs qualitative inference by inputting the qualitative expression of the time-series data of the influencing item, which is the output data of the factor estimation model, into the qualitative inference model.

As described above regarding the validity determination unit 184, the qualitative inference unit 188 uses the qualitative expression of the factor estimation model output data in order for the validity determination unit 184 to determine the validity of the factor estimation model output data.

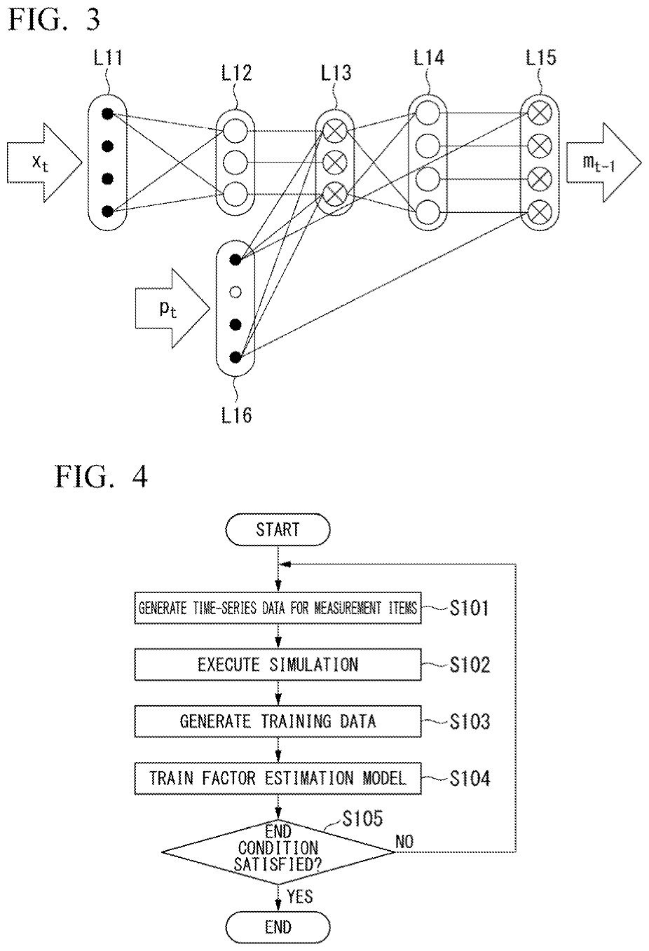

FIG. 4 is a flowchart showing an example of a processing procedure for the estimation device 100 to train the factor estimation model.

In the processing of FIG. 4, the training data acquisition unit 181 generates time-series data of a measurement item (Step S101).

Next, the simulator unit 187 inputs the time-series data of the measurement item generated by the training data acquisition unit 181 into the simulation model, and executes a simulation of the target 900 (Step S102).

The training data acquisition unit 181 generates training data by associating the time-series data of the measurement item generated in Step S101 with the time-series data of the influence item obtained as a result of the simulation in Step S102 (Step S103).

Next, the learning unit 182 uses the training data generated by the training data acquisition unit 181 to perform training of the factor estimation model (Step S104).

Then, the learning unit 182 determines whether or not a predetermined end condition is satisfied for the training of the factor estimation model (Step S105).

The end condition for the training of the factor estimation model is not limited to a particular condition, and various conditions may be used. For example, the learning unit 182 may determine whether or not the number of repetitions of the loop of processing from Step S101 to Step S105 is equal to or greater than a predetermined threshold value, and if it is determined as being equal to or greater than the threshold value, the end condition may be determined as being satisfied.

Alternatively, the learning unit 182 may use actual data or preliminarily prepared test data to calculate the evaluation value of the factor estimation model. Then, the learning unit 182 may determine whether or not the calculated evaluation value is equal to or greater than a predetermined threshold value, and if it is determined as being equal to or greater than the threshold value, the end condition may be determined as being satisfied.

If the learning unit 182 determines the end condition as not being satisfied (Step S105: NO), the process transitions to Step S101. In such a case, the estimation device 100 repeats the loop of processing from Step S101 to Step S105 to generate new training data and further perform training of the factor estimation model.

On the other hand, if the learning unit 182 determines the end condition as being satisfied (Step S105: YES), the estimation device 100 ends the processing of FIG. 4.

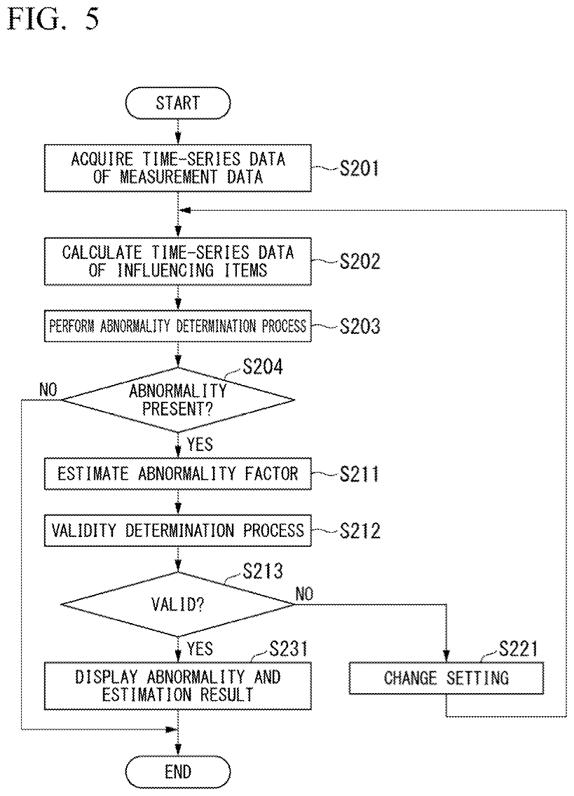

FIG. 5 is a flowchart showing an example of a processing procedure for the estimation device 100 to estimate an abnormality factor of the target 900 based on the time-series data of measurement data.

In the processing of FIG. 5, the factor estimation unit 183 acquires time-series data of measurement data (Step S201).

For example, the control unit 180 reads measurement data from the data received by the communication unit 110, associates it with measurement time information or received time information, and stores it in the storage unit 170. The control unit 180 causes the storage unit 170 to further store new measurement data while leaving the past measurement data stored in the storage unit 170, and the storage unit 170 thereby stores the time-series data of the measurement data. The factor estimation unit 183 acquires the time series data of the measurement data by reading the time-series data of the measurement data stored in the storage unit 170.

Next, the factor estimation unit 183 inputs the time-series data of the measurement data obtained in Step S201 to the factor estimation model, to calculate the time series data of the influencing item (Step S202).

Next, the abnormality estimation unit 186 performs an abnormality determination process in order to determine whether or not an abnormality is present in the target 900 (Step S203). As described above, the abnormality estimation unit 186 compares the measurement data with the measurement item data in the normal state of the target 900, and determines whether or not there is an item indicating a value that deviates from the value in the normal state by a predetermined condition or more.

Then, the abnormality estimation unit 186 determines whether or not there is an abnormality in the target 900 based on the process in Step S203 (Step S204).

For example, if an applicable item is determined as being present in Step S203, the abnormality estimation unit 186 determines an abnormality as being present in the target 900.

As described above, the abnormality estimation unit 186 may estimate the presence of an abnormality related to the target 900, based on the time-series data of the influencing item in addition to or instead of the abnormality presence determination based on the measurement data.

If the abnormality estimation unit 186 determines no abnormality as being present (Step S204: NO), the estimation device 100 ends the processing of FIG. 5.

On the other hand, if an abnormality is determined as being present (Step S204: YES), the factor estimation unit 183 estimates the factor of the abnormality (Step S211). As described above, the factor estimation unit 183 compares the time-series data of the influencing item in the normal state, with the time-series data of the influencing item in the abnormal state. The factor estimation unit 183 then estimates an item, for which a value that differs by a predetermined condition or more between normal and abnormal states, as the factor of the abnormality.

Alternatively, in Step S203 to Step S204 described above, if the abnormality estimation unit 186 determines whether or not an abnormality related to the target 900 is present based on the time-series data of the influencing item, the factor estimation unit 183 may determine the influencing item that has been determined as having an abnormality, as the factor of the abnormality.

Next, the validity determination unit 184 performs a process for determining the validity of the abnormality factor estimation result (Step S212).

As described above, the validity determination unit 184 may use qualitative inference performed by the qualitative inference unit 188 to determine the validity of the output data of the factor estimation model. In addition to or instead of the validity determination using the qualitative inference performed by the qualitative inference unit 188, the validity determination unit 184 may use a simulation of the target 900 performed by the simulator unit 187 to determine the validity of the output data of the factor estimation model.

Then, based on the process in Step S212, the validity determination unit 184 determines whether or not the abnormality factor estimation result is valid (Step S213).

If the abnormality factor estimation result is determined as not being valid (Step S213: NO), the validity determination unit 184 changes the setting for factor estimation (Step S221). As described above, the validity determination unit 184 may set a non-estimation target influencing item.

After Step S221, the process transitions to Step S202.

On the other hand, in Step S213, if the validity determination unit 184 determines the abnormality factor estimation result as being valid (Step S213: YES), the display unit 120 displays the abnormality and the abnormality factor estimation result under the control of the control unit 180 (Step S231).

After Step S231, the estimation device 100 ends the processing of FIG. 5.

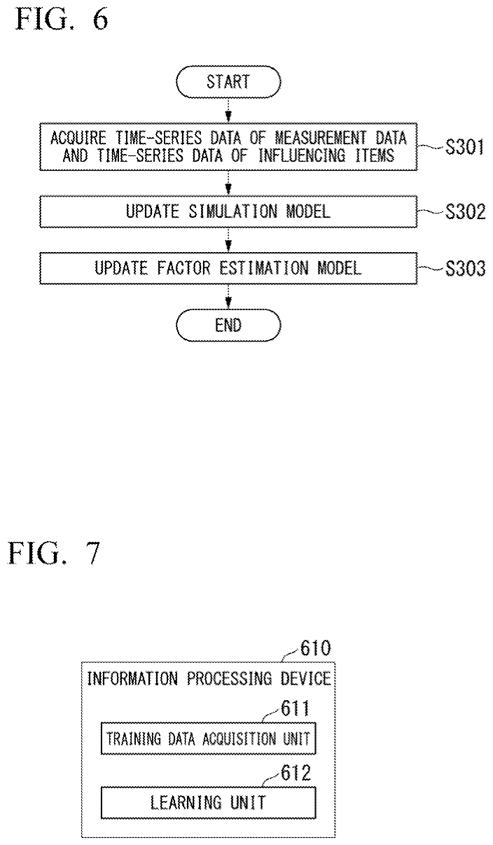

FIG. 6 is a flowchart showing an example of a processing procedure for the estimation device 100 to update the factor estimation model.

In the processing of FIG. 6, the model update unit 185 acquires time-series data of measurement data, and time-series data of influencing items at that time (Step S301).

Next, the model update unit 185 updates the simulation model (Step S302).

Then, the model update unit 185 updates the factor estimation model (Step S303). As described above, in accordance with the instruction of the model update unit 185, the training data acquisition unit 181 generates training data for training of the factor estimation model, using the updated simulation model. Then, in accordance with the instruction of the model update unit 185, the learning unit 182 performs training of the factor estimation model, using the training data generated by the training data acquisition unit 181.

After Step S303, the estimation device 100 ends the processing of FIG. 6.

As has been described in the foregoing, the training data acquisition unit 181 acquires training data that include time-series data of a measurement item and time-series data of an influencing item. The learning unit 182 uses the training data acquired by the training data acquisition unit 181 to perform training of the factor estimation model that takes an input of the time-series data of the measurement item and outputs the time-series data of the influencing item.

According to the estimation device 100, it is possible to estimate the time-series data of the influencing item based on the time-series data of the measurement data, using the factor estimation model. In such a case, it can be said that the time-series data of the influencing item obtained as the estimation result indicates the operation or the state of the surrounding environment that causes the event indicated in the time-series data of the measurement data. In this way, the estimation device 100 can estimate the factor of an event detected in relation to the target 900.

In the case of estimating the factor of a particular event indicated in the time-series data of the measurement data, as described above, the correlation between the event detected in relation to the target 900 and the item influencing the target 900 may be statistically analyzed in advance. It is expected that, based on this correlation, the factor of the particular event indicated in the time-series data of the measurement data can be extracted from the event indicated in the time-series data of the influencing item.

Also, according to the estimation device 100, it is possible to obtain a factor estimation model that receives an input of time-series data of measurement data and outputs time-series data of the influencing item. As a result, even in the case where the length of time is unknown from the time at which an operation on the target 900 and the surrounding environment state occurs, to the time at which the effect emerges on the state and the output of the target 900, the estimation device 100 can estimate the factor of an abnormality or the like, using the factor estimation model.

Moreover, the training data acquisition unit 181 acquires training data, based on the result of simulating the target 900 using the simulator.

As a result, in the estimation device 100, training data regarding various situations of the target 900 can be obtained even in the case where sufficient training data cannot be obtained depending on the measurement data, such as when the frequency of abnormality occurrence in the target 900 is not high. As described above, the measurement data referred to here are actual measurement data related to the target 900.

Moreover, the training data acquisition unit 181 acquires training data that include data obtained by adding noise to the time-series data of the influencing item obtained as a simulation result.

As a result, when measurement data acquired by the estimation device 100 contains noise, it is expected that training data that approximate the measurement data can be obtained and highly accurate training of the factor estimation model can be performed.

Also, the training data acquisition unit 181 acquires training data that include measurement item data in addition to the data based on the simulation result. As described above, the measurement data referred to here are actual measurement data related to the target 900.

According to the estimation device 100, it is expected that highly accurate learning can be performed by training the factor estimation model using training data that include actual measurement data.

Moreover, the factor estimation unit 183 receives designation of a non-estimation target item among influencing items, and estimates the value of the item that is not a non-estimation target.

This allows the factor estimation unit 183 to narrow down the estimation target factor. In this regard, the factor estimation unit 183 is expected to be able to perform highly accurate estimation of the factor of an event detected in relation to the target 900.

Also, the factor estimation unit 183 estimates the value of the item that is not a non-estimation target, using the factor estimation model adjusted so that the value of the non-estimation target item is a predetermined value for the item.

As a result, the factor estimation unit 183 can narrow down the estimation target factor as described above, and can further use the value of the non-estimation target item for factor estimation. In this regard, the factor estimation unit 183 is expected to be able to perform even more highly accurate estimation of the factor of an event detected in relation to the target 900.

Moreover, the factor estimation model is configured using a neural network. The factor estimation unit 183 uses the factor estimation model adjusted by performing at least any one of: switching the input value to one or more nodes of the neural network to a constant value; biasing the input to one or more nodes of the neural network; rewriting the weight coefficient of one or more edges of the neural network; and switching part or all of the neural network to another neural network.

In this way, the factor estimation unit 183 adjusts the neural network serving as a factor estimation model according to the structure of the neural network, so that the mechanism for adjustment can be made relatively simple. In this regard, the configuration of the estimation device 100 can be made relatively simple.

Moreover, the factor estimation unit 183 learns the method of adjusting the factor estimation model, for each item that may be designated as a non-estimation target or each combination thereof.

This eliminates the need for the user to set the adjustment method of the factor estimation model when a non-estimation target item is designated. According to the estimation device 100, the user's burden can be reduced in this regard.

Moreover, the validity determination unit 184 determines the validity of output data of the factor estimation model, based on input data to the factor estimation model.

If the factor estimation model is determined as not being valid, for example, the time-series data of the influencing item can be estimated again by changing the setting for calculation by the factor estimation model, and using the factor estimation model.

According to the validity determination unit 184, it is thus expected to be able to perform highly accurate estimation of the time-series data of the influencing item, and perform highly accurate estimation of the factor of an event detected in relation to the target 900.

Also, the validity determination unit 184 determines the validity of output data of the factor estimation model, based on the consistency between the inference result obtained through qualitative inference using the qualitative expression of the output data of the factor estimation model and the input data to the factor estimation model.

According to the estimation device 100, it is possible to determine the validity of the time-series data of the influencing item obtained as the output data of the factor estimation model, and if it is determined as not being valid, the time-series data of the influencing item can be estimated again.

According to the validity determination unit 184, it is thus expected to be able to perform highly accurate estimation of the time-series data of the influencing item, and perform highly accurate estimation of the factor of an event detected in relation to the target 900.

Moreover, the validity determination unit 184 determines the validity of the output data of the factor estimation model by comparing the simulation result obtained by inputting the output data of the factor estimation model to the simulator of the target 900, with the input data to the factor estimation model.

According to the estimation device 100, it is possible to determine the validity of the time-series data of the influencing item obtained as the output data of the factor estimation model, and if it is determined as not being valid, the time-series data of the influencing item can be estimated again.

According to the validity determination unit 184, it is thus expected to be able to perform highly accurate estimation of the time-series data of the influencing item, and perform highly accurate estimation of the factor of an event detected in relation to the target 900.

Also, the model update unit 185 updates the factor estimation model, using measurement data. As described above, the measurement data referred to here are actual measurement data related to the target 900.

Accordingly, the model update unit 185 can update the factor estimation model in accordance with the actual machine of the target 900, and can reflect changes in the characteristics of the actual machine of the target 900, such as deterioration over time, in the factor estimation model. According to the model update unit 185, in this respect, it is possible to improve the accuracy of the factor estimation model.

In addition, the abnormality estimation unit 186 estimates an abnormality related to the target 900, based on output data calculated by inputting measured data into the factor estimation model. As described above, the measurement data referred to here are actual measurement data related to the target 900.

As described above, when an abnormality occurs due to an operation performed on the target 900, it is conceivable that the operation that causes the abnormality is different from the normal operation. Also, there is a time lag between the moment at which the operation that causes an abnormality is performed and the moment at which the abnormality occurs, and it is conceivable that detection of the operation that causes an abnormality can be performed more quickly than detection of the abnormality itself. The abnormality estimation unit 186 estimates an abnormality related to the target 900 based on the time-series data of operations calculated by the factor estimation unit 183, so that it is expected to be able to detect the possibility of an abnormality before the abnormality is detected.

Similarly, also in the case where an abnormality is caused by the state of the surrounding environment of the target 900, then according to the abnormality estimation unit 186, it is expected to be able to detect the possibility of an abnormality before the abnormality is detected.

Also, as described above, when an abnormality occurs in the target 900, a case is conceivable where data that approximates the data in the normal state can be obtained as measurement data by performing an operation corresponding to the abnormality. In such a case, rather than using measurement data to detect an abnormality, detecting an abnormality using the data of operations on the target 900 will results in a greater difference from the normal state, and therefore there is a possibility of a successful abnormality detection with even higher accuracy. The abnormality estimation unit 186 estimates an abnormality related to the target 900 based on the time-series data of operations calculated by the factor estimation unit 183, so that it is expected to be able to detect an abnormality with even higher accuracy.

Similarly, also in the case where an abnormality is caused due to the state of the surrounding environment of the target 900, then according to the abnormality estimation unit 186, it is expected to be able to detect an abnormality with even higher accuracy.

FIG. 7 is a diagram showing a configuration example of an information processing device according to an example embodiment. In the configuration shown in FIG. 7, an information processing device 610 includes a training data acquisition unit 611 and a learning unit 612.

With such a configuration, the training data acquisition unit 611 acquires training data including time-series data of a measurement item related to the target and time-series data of an item that influences the target. The learning unit 612 uses the training data acquired by the training data acquisition unit 611 to perform training of the model that takes an input of the time-series data of the measurement item and outputs the time-series data of the item influencing the target.

The training data acquisition unit 611 corresponds to an example of the training data acquisition means. The learning unit 612 corresponds to an example of the learning means.

According to the information processing device 610, it is possible to estimate the time-series data of the item that influences the target, based on the time-series data of the measurement item, using the trained model. In such a case, it can be said that the time-series data of the item that influences the target, which is obtained as an estimation result, are the factor of the event indicated in the time-series data of the measurement item. In this way, the information processing device 610 can estimate the factor of an event detected in relation to the target.

In the case of estimating the factor of a particular event indicated in the time-series data of a measurement item, the correlation between the event detected in relation to the target, and the item influencing the target may be statistically analyzed in advance. It is expected that, based on this correlation, the factor of the particular event indicated in the time-series data of the measurement item can be extracted from the event indicated in the time-series data of the item influencing the target.

The training data acquisition unit 611 can be implemented using the function of the training data acquisition unit 181 shown in FIG. 1, for example. The learning unit 612 can be implemented using the function of the learning unit 182 shown in FIG. 1, for example.

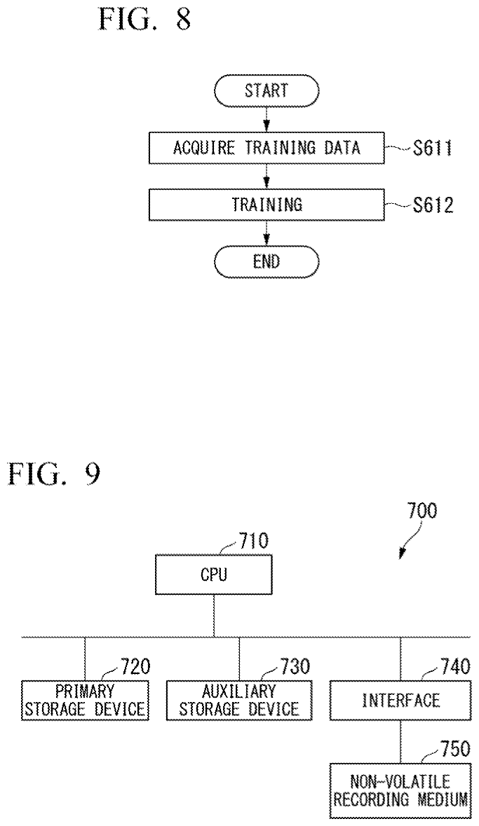

FIG. 8 is a diagram showing an example of a processing procedure in the information processing method according to an example embodiment. The information processing method shown in FIG. 8 includes a step of acquiring training data (Step S611) and a step of performing training (Step S612).

In the step of acquiring training data (Step S611), training data including time-series data of a measurement item related to the target and time-series data of an item that influences the target are acquired. In the step of performing training (Step S612), the training data obtained in Step S611 is used to perform training of the model that takes an input of time-series data of a measurement item and outputs time-series data of an item that influences the target.

The process of Step S611 can be performed using, for example, the function of the training data acquisition unit 181 shown in FIG. 1. The process of Step S612 can be performed using, for example, the function of the learning unit 182 shown in FIG. 1.

According to the method of FIG. 8, it is possible to estimate the time-series data of the item that influences the target based on the time-series data of the measurement item, using the trained model. In such a case, it can be said that the time-series data of the item that influences the target, which is obtained as an estimation result, are the factor of the event indicated in the time-series data of the measurement item. Thus, in the method of FIG. 8, it is possible to estimate the factor of an event detected in relation to the target.

In the case of estimating the factor of a particular event indicated in the time-series data of a measurement item, the correlation between the event detected in relation to the target, and the item influencing the target may be statistically analyzed in advance. It is expected that, based on this correlation, the factor of the particular event indicated in the time-series data of the measurement item can be extracted from the event indicated in the time-series data of the item influencing the target.

FIG. 9 is a schematic block diagram showing a configuration of a computer according to at least one of the example embodiments.

In the configuration shown in FIG. 9, a computer 700 includes a CPU 710, a primary storage device 720, an auxiliary storage device 730, an interface 740, and a non-volatile recording medium 750.

One or more of the estimation device 100 and the information processing device 610 or part thereof may be implemented in the computer 700. In such a case, operations of the respective processing units described above are stored in the auxiliary storage device 730 in the form of a program. The CPU 710 reads out the program from the auxiliary storage device 730, loads it on the primary storage device 720, and executes the processing described above according to the program. Moreover, the CPU 710 reserves, according to the program, storage regions corresponding to the respective storage units mentioned above, in the primary storage device 720. Communication between each device and other devices is executed by the interface 740 having a communication function and communicating under the control of the CPU 710. The interface 740 also has a port for the non-volatile recording medium 750, and reads information from the non-volatile recording medium 750 and writes information to the non-volatile recording medium 750.

In the case where the estimation device 100 is implemented in the computer 700, operations of the control unit 180 and each component thereof are stored in the form of a program in the auxiliary storage device 730. The CPU 710 reads out the program from the auxiliary storage device 730, loads it on the primary storage device 720, and executes the processing described above according to the program.

Moreover, the CPU 710 reserves, according to the program, a storage region corresponding to the storage unit 170 mentioned above, in the primary storage device 720.

Communication with another device performed by the communication unit 110 is executed by the interface 740 having a communication function, and operating under the control of the CPU 710.

Display performed by the display unit 120 is executed by the interface 740 having a display device, and displaying various images under the control of the CPU 710.

Acceptance of a user operation through the operation input unit 130 is executed by the interface 740 having input devices such as a keyboard and a mouse, accepting the user operation, and outputting information indicating the accepted user operation to CPU 710.

In the case where the information processing device 610 is implemented in the computer 700, operations of the training data acquisition unit 611 and the learning unit 612 are stored in the form of a program in the auxiliary storage device 730. The CPU 710 reads out the program from the auxiliary storage device 730, loads it on the primary storage device 720, and executes the processing described above according to the program.

Also, the CPU 710 reserves a storage region in the primary storage device 720 for the processing to be performed by the information processing device 610 according to the program.

Communication between the information processing device 610 and other devices is executed by the interface 740 having a communication function, and operating under the control of the CPU 710.

Interaction between the information processing device 610 and a user is executed by the interface 740 having an input device and an output device, presenting information to the user through the output device under the control of CPU 710, and accepting user operations through the input device.

Any one or more of the programs described above may be recorded in the non-volatile recording medium 750. In such a case, the interface 740 may read the program from the non-volatile recording medium 750. Then, the CPU 710 directly executes the program read by the interface 740, or it may be temporarily stored in the primary storage device 720 or the auxiliary storage device 730 and then executed.

It should be noted that a program for executing some or all of the processes performed by the estimation device 100 and the information processing device 610 may be recorded on a computer-readable recording medium, and the program recorded on the recording medium may be read into and executed on a computer system, to thereby perform the processing of each unit. The “computer system” here includes an OS (operating system) and hardware such as peripheral devices.

Moreover, the “computer-readable recording medium” referred to here refers to a portable medium such as a flexible disk, a magnetic optical disk, a ROM (Read Only Memory), and a CD-ROM (Compact Disc Read Only Memory), or a storage device such as a hard disk built in a computer system. The above program may be a program for realizing a part of the functions described above, and may be a program capable of realizing the functions described above in combination with a program already recorded in a computer system.

The example embodiments of the present invention have been described in detail with reference to the drawings. However, the specific configuration of the invention is not limited to the example embodiments, and may include designs and so forth that do not depart from the scope of the present invention.

Furthermore, part or all of the above example embodiments can be described as but are not limited to the following supplementary notes.

### (Supplementary Note 1)

An information processing device comprising:
a training data acquisition means that acquires training data, the training data including time-series data of a measurement item regarding a target and time-series data of an item that influences the target; and
a learning means that trains, by using the training data, a model that receives an input of time-series data of the measurement item and outputs time-series data of the item that influences the target.

### (Supplementary Note 2)

The information processing device according to Supplementary Note 1,
wherein the training data acquisition means acquires the training data based on a simulation result of the target using a simulator.

### (Supplementary Note 3)

The information processing device according to Supplementary Note 2,
wherein the training data acquisition means acquires the training data including data obtained by adding noise to data of the simulation result.

### (Supplementary Note 4)

The information processing device according to Supplementary Note 2 or 3,
wherein the training data acquisition means acquires the training data including actual measurement data of the measurement item in addition to data based on the simulation result.

### (Supplementary Note 5)

The information processing device according to any one of Supplementary Notes 1 to 4, further comprising:
an estimation means that receives designation of a non-estimation target item among items influencing the target, and estimates a value of an item that is not the non-estimation target.

### (Supplementary Note 6)

The information processing device according to Supplementary Note 5,
wherein the estimation means estimates the value of the item that is not the non-estimation target, using the model that is adjusted so that the value of the non-estimation target item is a predetermined value for the item.

### (Supplementary Note 7)

The information processing device according to Supplementary Note 6,
wherein the model is configured using a neural network, and
wherein the estimation means uses the model that is adjusted by performing at least any one of: switching an input value to one or more nodes of the neural network to a constant value; biasing an input to one or more nodes of the neural network; rewriting a weight coefficient of one or more edges of the neural network; and switching part or all of the neural network to another neural network.

### (Supplementary Note 8)

The information processing device according to Supplementary Note 6 or 7,
wherein the estimation means learns a method of adjusting the model for each item that has a possibility of being designated as the non-estimation target item or each combination thereof

### (Supplementary Note 9)

The information processing device according to any one of Supplementary Notes 1 to 8, further comprising:
a validity determination means that determines validity of output data of the model, based on input data to the model.

### (Supplementary Note 10)

The information processing device according to Supplementary Note 9,
wherein the validity determination means determines the validity of the output data of the model, based on a consistency between an inference result obtained by qualitative inference using a qualitative expression of the output data of the model, and the input data to the model.

### (Supplementary Note 11)

The information processing device according to Supplementary Note 9 or 10,
wherein the validity determination means determines the validity of the output data of the model by comparing a simulation result obtained by inputting the output data of the model into a simulator of the target, with the input data to the model.

### (Supplementary Note 12)

The information processing device according to any one of Supplementary Notes 1 to 11, further comprising:
a model update means that updates the model, using actual measurement data of the measurement item.

### (Supplementary Note 13)

The information processing device according to any one of Supplementary Notes 1 to 12, further comprising:
an abnormality estimation means that estimates an abnormality related to the target, based on output data calculated by inputting actual measurement data of the measurement item into the model.

### (Supplementary Note 14)

An information processing method executed by a computer, comprising:
acquiring training data, the training data including time-series data of a measurement item regarding a target and time-series data of an item that influences the target; and
training, by using the training data, a model that receives an input of time-series data of the measurement item and outputs time-series data of the item that influences the target.

### (Supplementary Note 15)

A recording medium having recorded therein a program causing a computer to execute:
acquiring training data, the training data including time-series data of a measurement item regarding a target and time-series data of an item that influences the target; and
training, by using the training data, a model that receives an input of time-series data of the measurement item and outputs time-series data of the item that influences the target.

### INDUSTRIAL APPLICABILITY

The example embodiments of the present invention may be applied to an information processing device, an information processing method, and a recording medium.

### DESCRIPTION OF REFERENCE SYMBOLS

100 Estimation device
110 Communication unit
120 Display unit
130 Operation input unit
170 Storage unit
180 Control unit
181, 611 Training data acquisition unit
182, 612 Learning unit
183 Factor estimation unit
184 Validity determination unit
185 Model update unit
186 Abnormality estimation unit
187 Simulator unit
188 Qualitative inference unit
610 Information processing device

What is claimed is:

1. An information processing device comprising:
a memory configured to store instructions; and
a processor configured to execute the instructions to:
acquire training data, the training data including time-series data of a measurement item regarding a target and time-series data of an item that influences the target; and
train, by using the training data, a model that receives an input of time-series data of the measurement item and outputs time-series data of the item that influences the target.

2. The information processing device according to claim 1,
wherein the processor is configured to execute the instructions to acquire the training data based on a simulation result of the target using a simulator.

3. The information processing device according to claim 2,
wherein the processor is configured to execute the instructions to acquire the training data including data obtained by adding noise to data of the simulation result.

4. The information processing device according to claim 2,
wherein the processor is configured to execute the instructions to acquire the training data including actual measurement data of the measurement item in addition to data based on the simulation result.

5. The information processing device according to claim 1,
wherein the processor is configured to execute the instructions to receive designation of a non-estimation target item among items influencing the target, and estimates a value of an item that is not the non-estimation target.

6. The information processing device according to claim 5,
wherein the processor is configured to execute the instructions to estimate the value of the item that is not the non-estimation target, using the model that is adjusted so that the value of the non-estimation target item is a predetermined value for the item.

7. The information processing device according to claim 6,
wherein the model is configured using a neural network, and
wherein the processor is configured to execute the instructions to use the model that is adjusted by performing at least any one of: switching an input value to one or more nodes of the neural network to a constant value; biasing an input to one or more nodes of the neural network; rewriting a weight coefficient of one or more edges of the neural network; and switching part or all of the neural network to another neural network.

8. The information processing device according to claim 6,
wherein the processor is configured to execute the instructions to learn a method of adjusting the model for each item that has a possibility of being designated as the non-estimation target item or each combination thereof.

9. The information processing device according to claim 1,
wherein the processor is configured to execute the instructions to determine validity of output data of the model, based on input data to the model.

10. The information processing device according to claim 9,
wherein the processor is configured to execute the instructions to determine the validity of the output data of the model, based on a consistency between an inference result obtained by qualitative inference using a qualitative expression of the output data of the model, and the input data to the model.

11. The information processing device according to claim 9,
wherein the processor is configured to execute the instructions to determine the validity of the output data of the model by comparing a simulation result obtained by inputting the output data of the model into a simulator of the target, with the input data to the model.

12. The information processing device according to claim 1,
wherein the processor is configured to execute the instructions to update the model, using actual measurement data of the measurement item.

13. The information processing device according to claim 1,
wherein the processor is configured to execute the instructions to estimate an abnormality related to the target, based on output data calculated by inputting actual measurement data of the measurement item into the model.

14. An information processing method executed by a computer, comprising:
acquiring training data, the training data including time-series data of a measurement item regarding a target and time-series data of an item that influences the target; and
training, by using the training data, a model that receives an input of time-series data of the measurement item and outputs time-series data of the item that influences the target.

15. A non-transitory recording medium having recorded therein a program causing a computer to execute:
acquiring training data, the training data including time-series data of a measurement item regarding a target and time-series data of an item that influences the target; and
training, by using the training data, a model that receives an input of time-series data of the measurement item and outputs time-series data of the item that influences the target.
